(19) United States
(12) Patent Application Publication
(10) Pub. No.: US 2013/0092962 A1
(43) Pub. Date: Apr. 18, 2013

(54) LIGHT EMITTING DEVICE (LED), MANUFACTURING METHOD THEREOF, AND LED MODULE USING THE SAME

(71) Applicants: Ho Sun Paek, Suwon-si (KR); Hak Hwan Kim, Suwon-si (KR); Ill Heung Choi, Hwaseong-si (KR); Kyung Mi Moon, Suwon-si (KR)

(72) Inventors: Ho Sun Paek, Suwon-si (KR); Hak Hwan Kim, Suwon-si (KR); Ill Heung Choi, Hwaseong-si (KR); Kyung Mi Moon, Suwon-si (KR)

(73) Assignee: SAMSUNG ELECTRONICS CO., LTD., Suwon-si (KR)

(21) Appl. No.: 13/655,100

(22) Filed: Oct. 18, 2012

(30) Foreign Application Priority Data
Oct. 18, 2011 (KR) 10-2011-0106294

(51) Int. Cl. H01L 33/08; H01L 33/62

(52) U.S. Cl. 257/88; 257/99; 438/38; 257/E33.012; 257/E33.066

(57) ABSTRACT

A light emitting device (LED), a manufacturing method thereof, and an LED module using the same. The LED may include a first semiconductor layer, an active layer, and a second semiconductor layer formed sequentially on a light-transmitting substrate, a first electrode formed in a region exposed by removing a part of the first semiconductor layer, a second electrode formed on the second semiconductor layer, a passivation layer formed on the first electrode and the second electrode to expose a region of the first electrode and a region of the second electrode, a first bump formed in a first region including the first electrode exposed through the passivation layer, and extended to another region of the second electrode on which the passivation layer is formed, and a second bump formed in a second region including the second electrode exposed through the passivation layer.

### CROSS-REFERENCE TO RELATED APPLICATIONS

This application claims priority under 35 U.S.C. §119 from Korean Patent Application No. 10-2011-0106294, filed on Oct. 18, 2011, in the Korean Intellectual Property Office, the disclosure of which is incorporated herein by reference in its entirety.

### BACKGROUND

1. Field

The present general inventive concept relates to a light emitting device (LED), a manufacturing method thereof, and an LED module using the same, and more particularly, to an LED having a bump structure to improve a bond performance between the LED and a substrate during a flip chip bonding process, a manufacturing method thereof, and an LED module using the same.

2. Description of the Related Art

A light emitting device (LED) refers to a semiconductor device that may emit lights of various colors by forming a light emitting source by changing a material of a compound semiconductor, for example, gallium arsenide (GaAs), aluminum gallium arsenide (AlGaAs), gallium nitride (GaN), gallium indium phosphide (GaInP), and the like. The LED may be manufactured in a modular form.

A conventional LED module is manufactured by mounting an LED on a package substrate to be manufactured in a package form, and bonding the LED package on the substrate. However, such a packaging process of the LED of the conventional LED module results in an increase in not only a manufacturing time and a manufacturing cost, but also an increase in an overall size of the module. In order to resolve these problems, an LED module of a chip on board (COB) type in which an LED is bonded directly to a substrate has been developed.

The LED module of the COB type is manufactured by bonding an LED on a substrate including a metallic pattern, using a bump. However, since at least two bumps formed in the LED have different heights, areas, and shapes, a bond performance between the substrate and the LED decreases. Accordingly, a reliability of the LED module may be decreased by a chip separation, and heat emission efficiency may be decreased by a reduction of a bonded area.

### SUMMARY

In general, the present inventive concept provides a light emitting device (LED) having a bump structure to improve a bond performance between the LED and a substrate during a flip chip bonding process, a manufacturing method thereof, and an LED module using the same.

Additional features and utilities of the present general inventive concept will be set forth in part in the description which follows and, in part, will be obvious from the description, or may be learned by practice of the general inventive concept.

The foregoing and/or other features and utilities of the present general inventive concept are achieved by providing an LED including a first semiconductor layer, an active layer, and a second semiconductor layer formed sequentially on a light-transmitting substrate, a first electrode formed in an indented region of the first semiconductor layer by removing a part of the first semiconductor layer, a second electrode formed on the second semiconductor layer, a passivation layer formed on the first electrode and the second electrode to expose a region of the first electrode and a region of the second electrode, a first bump formed in a first region including the first electrode exposed through the passivation layer, and extended to another region of the second electrode on which the passivation layer is formed, and a second bump formed in a second region including the second electrode exposed through the passivation layer.

The second electrode may include a plurality of electrode pads formed on the second semiconductor layer, and an intermediate connecting pad formed on the plurality of electrode pads.

The first region and the second region may have bilateral symmetry on the second semiconductor layer.

The first bump and the second bump may have identical heights based on the second semiconductor layer.

The first region and the second region may have identical areas.

The foregoing and/or other features and utilities of the present general inventive concept may also be achieved by providing a method of manufacturing an LED, the method including forming a first semiconductor layer, an active layer, and a semiconductor layer, sequentially, on a light-transmitting substrate, removing a part of the first semiconductor layer to form an indent within the first semiconductor layer, forming a first electrode within the indent of the first semiconductor layer, forming a second electrode on the second semiconductor layer, forming a passivation layer on the first electrode and the second electrode, etching the passivation layer to expose a region of the first electrode and a region of the second electrode, forming a first bump in a first region including the first electrode exposed through the passivation layer, and extended to another region of the second electrode on which the passivation layer is formed, and forming a second bump in a second region including the second electrode exposed through the passivation layer.

The forming of the second electrode may include forming a plurality of electrode pads on the second semiconductor layer, and forming an intermediate connecting pad on the plurality of electrode pads.

The forming the first bump and the forming the second bump may include disposing, on the second semiconductor layer, a mask including a hole at a position corresponding to the first region and the second region, and screen-printing a metallic material on the hole.

The forming of the first bump and the forming of the second bump may include bumping a solder ball in the first region and the second region.

The first region and the second region may have bilateral symmetry on the second semiconductor layer.

The forming of the first bump may include forming the first bump to have a height identical to a height of the second bump based on the second semiconductor layer.

The first region and the second region may have identical areas.

The passivation layer may be formed of any one selected from a group consisting of silicon oxide (SiOₓ), silicon nitride (SiNₓ), and silicon oxy-nitride (SiOₓN_{y}).

The foregoing and/or other features and utilities of the present general inventive concept may also be achieved by providing an LED module including a substrate comprising a first metallic pattern and a second metallic pattern, and at least one of LEDs that is flip chip bonded on the substrate, and the at least one LED may include a first electrode and a second electrode formed on a face of a light emitting structure, a passivation layer formed on the first electrode and the second electrode to expose a region of the first electrode and a region of the second electrode, a first bump formed in a first region including the first electrode exposed through the passivation layer, and extended to another region of the second electrode on which the passivation layer is formed, and bonded to the first metallic pattern, and a second bump formed in a second region including the second electrode exposed through the passivation layer, and bonded to the second metallic pattern.

The first bump and the second bump may have identical heights based on the light emitting structure.

### BRIEF DESCRIPTION OF THE DRAWINGS

These and/or other features and utilities of the present general inventive concept will become apparent and more readily appreciated from the following description of exemplary embodiments, taken in conjunction with the accompanying drawings of which:

FIG. 1 is a top view of a structure of a light emitting device (LED) according to an exemplary embodiment of the present general inventive concept;

FIG. 2 is a cross-sectional view of the LED of FIG. 1 that is cut along a line I-I′;

FIG. 3 is a top view of a structure of an LED according to another exemplary embodiment of the present general inventive concept;

FIG. 4 is a cross-sectional view of the LED of FIG. 3 that is cut along a line L-L′;

FIGS. 5 through 8 are cross-sectional views to describe a method of manufacturing an LED according to an exemplary embodiment of the present general inventive concept; and

FIG. 9 is a cross-sectional view of an LED module of a flip chip bonding scheme according to an exemplary embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below to explain the present general inventive concept while referring to the figures.

When it is determined that a detailed description is related to a related known function or configuration which may make the purpose of the present invention unnecessarily ambiguous in the description of the present invention, such detailed description will be omitted. Also, terminologies used herein are defined to appropriately describe the exemplary embodiments of the present invention and thus may be changed depending on a user, the intent of an operator, or a custom. Accordingly, the terminologies must be defined based on the following overall description of this specification.

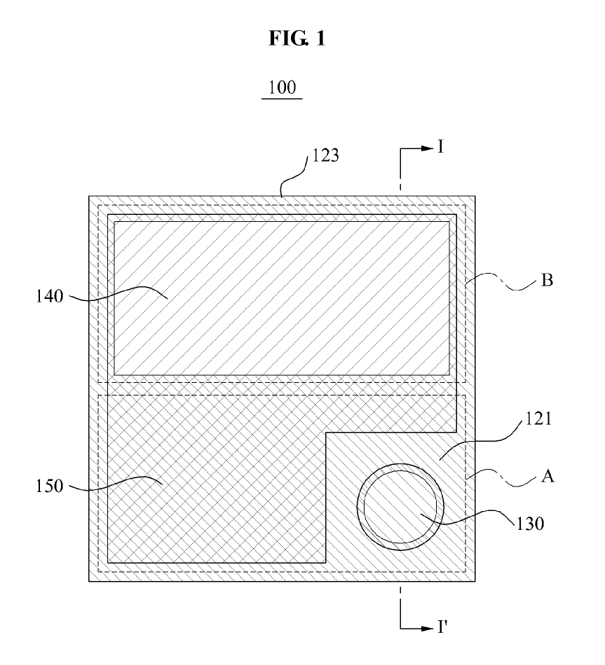

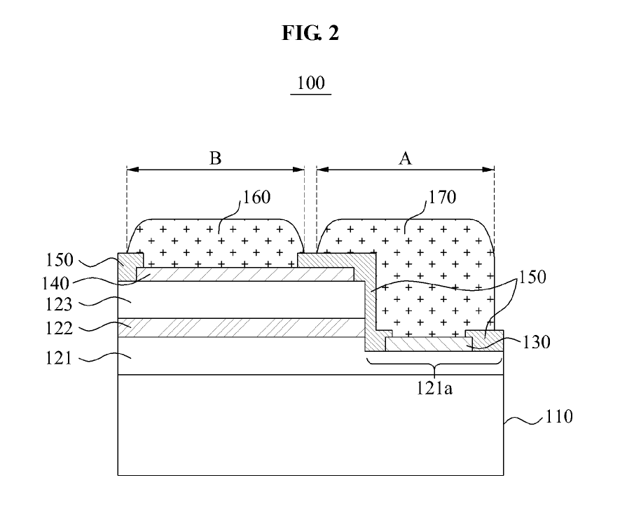

FIG. 1 is a top view of a structure of a light emitting device (LED) 100 according to an exemplary embodiment of the present general inventive concept while. FIG. 2 is a cross-sectional view of the LED 100 of FIG. 1 that is cut along a line I-I′.

Referring to FIG. 2, the LED 100 may include a light-transmitting substrate 110, a first semiconductor layer 121, an active layer 122, a second semiconductor layer 123, a first electrode 130, a second electrode 140, a passivation layer 150, a first bump 170, and a second bump 160.

In FIG. 1, although only the first electrode 130 formed on the first semiconductor layer 121, and the second electrode 140 formed on the second semiconductor layer 123 are illustrated, the LED 100 may further include the first bump 170 and the second bump 160, as illustrated in FIG. 2.

The first semiconductor layer 121, the active layer 122, and the second semiconductor layer 123 may be formed on the light-transmitting substrate 110 to form a light-emitting structure. The light-transmitting substrate 110 may be a sapphire substrate or a silicon carbide (SiC) substrate, but is not limited thereto.

The first semiconductor layer 121 may include an indented region 121a by removing a portion of the first semiconductor layer 121 via an etching process.

The first electrode 130 may be formed in the indented region 121a of the first semiconductor layer 121. The second electrode 140 may be formed on the second semiconductor layer 123.

The first electrode 130 and the second electrode 140 may be formed in different areas. For example, as illustrated in FIG. 1, the first electrode 130 may be formed within the indented region 121a of the first semiconductor layer 121, which is only a portion of the first semiconductor layer 121, whereas the second electrode 140 may be formed in an entire region, excluding an edge region of the second semiconductor layer 123. That is, positions and areas of the first electrode 130 and the second electrode 140 may be variable, depending on various exemplary embodiments.

The passivation layer 150 may be formed on the first electrode 130 and the second electrode 130 to expose one region of the first electrode 130 and one region of the second electrode 140. That is, another region of the first electrode 130 and another region of the second electrode 140 may be covered with the passivation layer 150 and thus, may not be exposed. The above-mentioned another regions of the first electrode 130 and the second electrode 140 may be outer regions thereof.

The first bump 170 may be formed in a first region A. The first region A may refer to a region including a portion of the first electrode 130 that is exposed through the passivation layer 150, and which is extended to the another region of the second electrode 140 in which the passivation layer 150 may be formed. That is, the first bump 170 may not be formed on a portion of the second electrode 140 that is exposed through the passivation layer 150, but may be formed on the second electrode 140 that is covered by the passivation layer 150. In this instance, the first bump 170 may not be electrically connected to the second electrode 140.

The second bump 160 may be formed in a second region B. The second region B may refer to a region including a portion of the second electrode 140 that is exposed through the passivation layer 150.

In FIGS. 1 and 2, the another region of the second electrode 140 may not be in direct contact with the second bump 160. However, the LED 100 may be operated via reception of an electrical signal through the portion of second electrode 140 that is exposed through the passivation layer 150.

The first region A in which the first bump 170 may be formed, and the second region B in which the second bump 160 may be formed may have bilateral symmetry on the second semiconductor layer 123.

Since the first bump 170 may be in contact with the first electrode 130, and may be formed to be extended to a portion of the another region of the second electrode 140, an area of the first bump 170 may be adjustable. Accordingly, by setting an area of the first region A and an area of the second region B to be identical to each other, the first bump 170 and the second bump 160 may have identical areas.

A percentage of an area occupied by the first bump 170 and the second bump 160 on the second semiconductor layer 123 may be adjusted to be in the range of about 75% to 95%. According to a result of a general simulation, when an area of bumps increases by 11% compared to an area of an LED, a temperature of an inner junction of the LED is reduced by 2%. Accordingly, by increasing the percentage of the area of the first bump 170 and the second bump 160, an area bonded between the LED and a substrate during a flip chip bonding process may increase, thereby a heat emission efficiency may be improved.

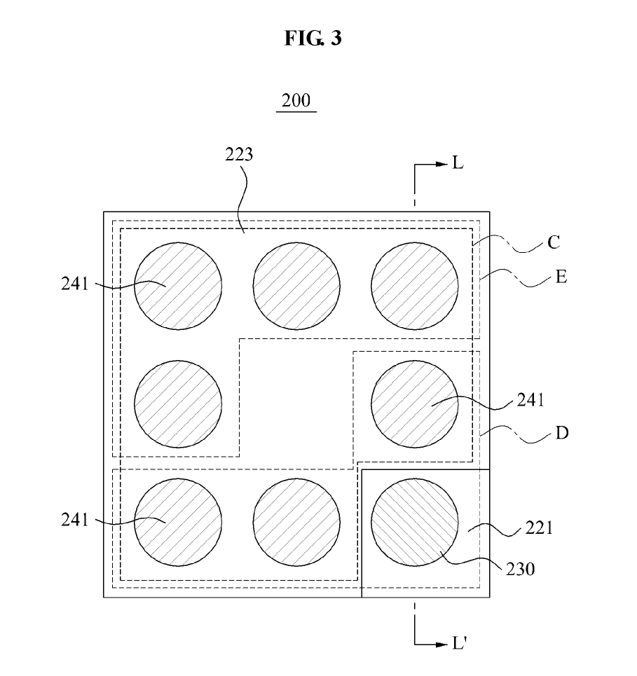

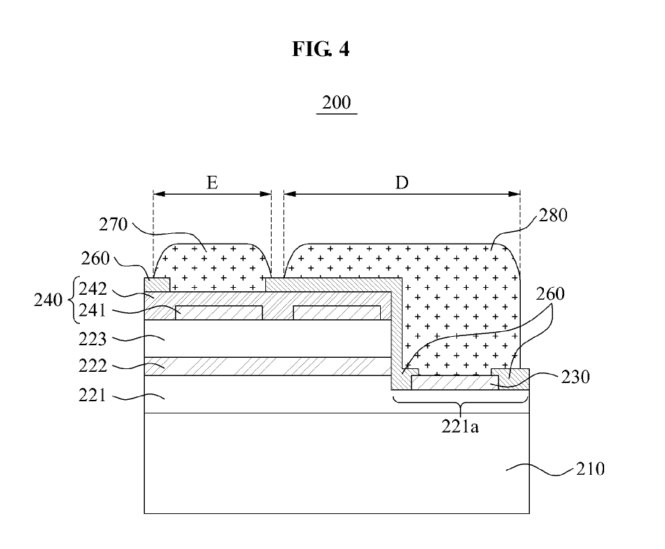

FIG. 3 is a top view of a structure of an LED 200 according to another exemplary embodiment of the present general inventive concept. FIG. 4 is a cross-sectional view of the LED 200 of FIG. 3 that is cut along a line L-L′.

Referring to FIG. 4, the LED 200 may include a light-transmitting substrate 210, a first semiconductor layer 221, an active layer 222, a second semiconductor layer 223, a first electrode 230, a second electrode 240, a passivation layer 260, a first bump 280, and a second bump 270. In FIG. 4, the second electrode 240 may include a plurality of electrode pads 241, and an intermediate connecting pad 242.

In FIG. 3, although only the first electrode 230 formed on the first semiconductor layer 221, and the plurality of electrode pads 241 formed on the second semiconductor layer 223 are illustrated, the LED 200 may further include the intermediate connecting pad 242, the passivation layer 260, the first bump 280, and the second bump 270, as illustrated in FIG. 4.

The first semiconductor layer 221, the active layer 222, and the second semiconductor layer 223 may be formed sequentially on the light-transmitting substrate 210.

The first electrode 230 may be formed in an indented region 221a of the first semiconductor layer 221.

The second electrode 240 may be formed on the second semiconductor layer 223. As aforementioned, the second electrode 240 may include the plurality of electrode pads 241, and the intermediate connecting pad 242.

The second electrode 240 illustrated in FIGS. 3 and 4 may include the plurality of electrode pads 241 formed to be divided on the second semiconductor layer 223, whereas the second electrode 140 illustrated in FIGS. 1 and 2 may be formed as a single layer on the second semiconductor layer 123.

The intermediate connecting pad 242 may be formed on the plurality of electrode pads 241. Accordingly, the intermediate connecting pad 242 may be formed in an electrode region C including both the second semiconductor layer 223 and the plurality of electrode pads 241, and may be in contact with the plurality of electrode pads 241.

The intermediate connecting pad 242 may be formed of a metallic material to electrically connect the plurality of electrode pads 241 to each other. Also, the intermediate connecting pad 242 may be formed of a metallic material having a great thermal conductivity to rapidly transfer heat generated in a light emitting structure.

The passivation layer 260 may be formed on the first electrode 230 and the intermediate connecting pad 242 to expose a region of the first electrode 230 and a region of the intermediate connecting pad 242.

The first bump 280 may be formed in a first region D including a portion of the first electrode 230 that is exposed through the passivation layer 260, and which is extended to another region of the intermediate connecting pad 242 on which the passivation layer 260 may be formed. That is, the first bump 280 may be in contact with the first electrode 230, and may be extended to a region of the intermediate connecting pad 242 that is covered by the passivation layer 260.

The second bump 270 may be formed in a second region E including a portion of the intermediate connecting pad 242 that is exposed through the passivation layer 260.

Referring to FIGS. 3 and 4, designs of the first bump 280 and the second bump 270 may be changed by changing positions, areas, and shapes of the first region D and the second region E. Accordingly, a diversity and number of different types of equipment to perform a bump manufacturing process and a flip chip bonding process may be provided and thus, a manufacturing cost may be reduced during mass production.

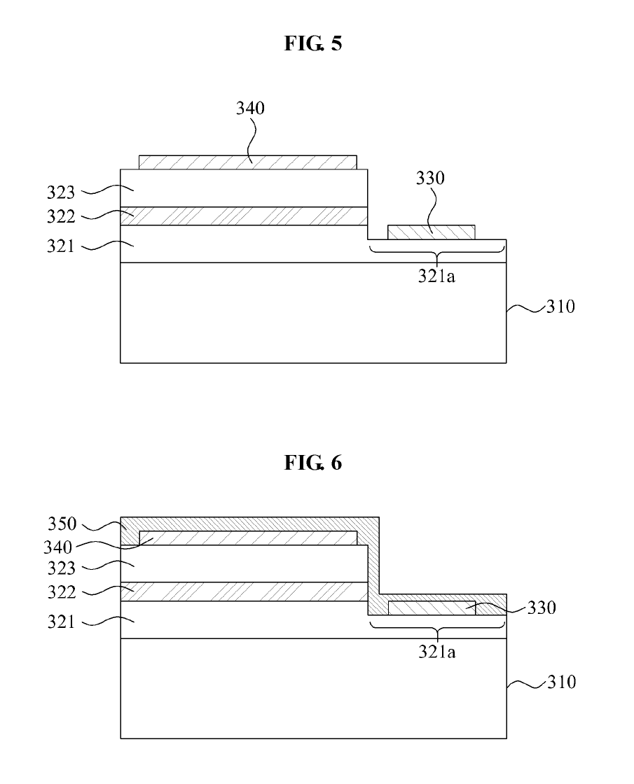

FIGS. 5 through 8 are cross-sectional views to describe a method of manufacturing an LED according to an exemplary embodiment of the present general inventive concept.

Referring to FIG. 5, the method may include a process of forming a first electrode 330 and a second electrode 340 on a light emitting structure. In particular, the light emitting structure may be created by forming a first semiconductor layer 321, an active layer 322, and a second semiconductor layer 323, sequentially on a light-transmitting substrate 310, forming the first electrode 330 on the first semiconductor layer 321, and forming the second electrode 340 on the second semiconductor layer 323. Accordingly, the light emitting structure may be mesa-etched so that a portion (i.e., an indented region 321a) of the first semiconductor layer 321 may be indented. The first electrode 330 may be formed in the indented region 321a of the first semiconductor layer 321.

Referring to FIG. 6, the method may include a process of forming a passivation layer 350 on the first electrode 330 and the second electrode 340. In particular, the passivation layer 350 may be formed by depositing any one of silicon oxide (SiOₓ), silicon nitride (SiNₓ), and silicon oxy-nitride (SiOₓN_{y}) on the mesa-etched first semiconductor layer 321, a side surface of the mesa-etched indented region 321a, and the second semiconductor layer 323. Accordingly, a height of the passivation layer 350 may be determined so that both the first electrode 330 and the second electrode 320 may be covered by the passivation layer 350.

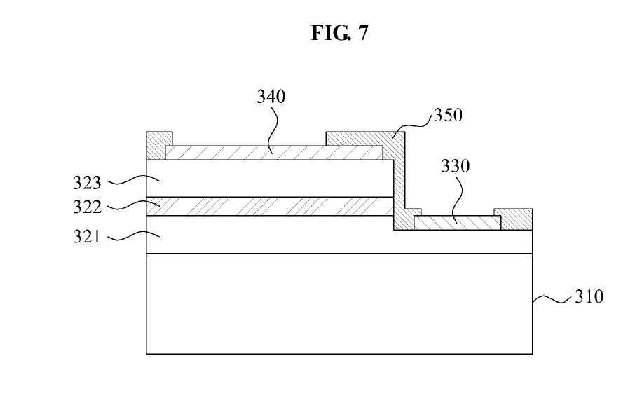

Referring to FIG. 7, the method may include a process of etching the passivation layer 350 to expose a region of the first electrode 330 and a region of the second electrode 340. In this instance, the passivation layer 350 may be etched in view of positions, areas, and shapes of a first region in which a first bump may be formed, and a second region in which a second bump may be formed.

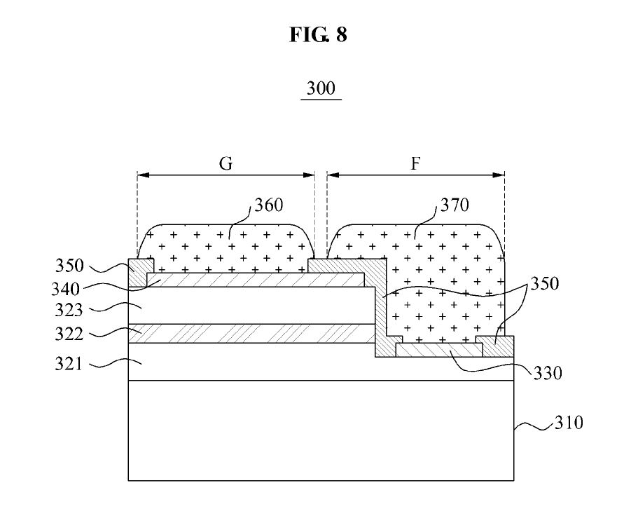

Referring to FIG. 8, the method may include a process of forming a first bump 370 and a second bump 360. In particular, the first bump 370 may be formed in a first region F including the first electrode 330 that is exposed through the passivation layer 350, and extended to another region of the second electrode 340 in which the passivation layer 350 may be formed. In this instance, the other region of the second electrode 340 may refer to a region of the second electrode 340 that may not be exposed through the passivation layer 350. Also, the second bump 360 may be formed in a second region G including the second electrode 340 that is exposed through the passivation layer 350.

The first bump 370 and the second bump 360 may be formed using a screen print scheme or a solder ball forming scheme, but is not limited thereto. In the screen print scheme, a mask (not illustrated) including a hole at a position corresponding to the first region F and the second region G may be installed on the second semiconductor layer 323. By screen-printing a metallic material on the hole of the mask, the first bump 370 may be formed in the first region F and the second bump 360 may be formed in the second region G.

In the solder ball forming scheme, the first bump 370 and the second bump 360 may be formed by applying a solder ball to the first region F and the second region G. As stated above, a scheme of forming the first bump 370 and the second bump 360 is not limited to the aforementioned schemes, and a conductive adhesive may be alternatively used. In FIG. 8, the first bump 370 and the second bump 360 may be formed to have identical heights based on the second semiconductor layer 323. Also, the first region 370 and the second region 360 may be formed to have identical areas and to have bilateral symmetry, on the second semiconductor layer 323.

Although not illustrated in FIGS. 5 through 8, an intermediate connecting pad (not illustrated) may be further formed on a plurality of electrode pads when the second electrode 340 is formed into the plurality of electrode pads on the second semiconductor layer 323, rather than formed into a single layer on the second semiconductor layer 323. In particular, a single intermediate connecting pad may be in contact with the plurality of electrode pads to transfer, to the plurality of electrode pads, an electrical signal transferred from outside the LED 300.

When the intermediate pad is formed, the passivation layer 350 may be formed on the first electrode 330 and the intermediate connecting pad, and may be etched to expose a region of the first electrode 330 and a region of the intermediate connecting pad. A process of forming a first bump and a second bump on the first electrode 330 and the intermediate connecting pad may be performed using the scheme illustrated in FIG. 8. The LED 200 illustrated in FIGS. 3 and 4 may also be manufactured through the aforementioned processes.

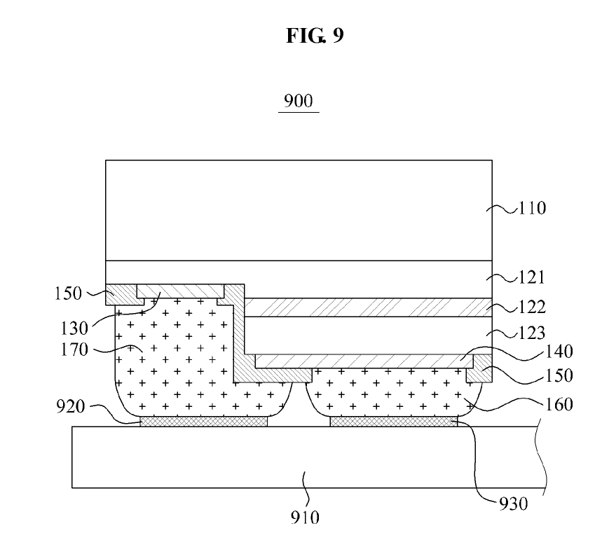

FIG. 9 is a cross-sectional view of an LED module 900 of a flip chip bonding scheme according to an exemplary embodiment of the present general inventive concept. Referring to FIG. 9, the LED module 900 may correspond to a module of a chip on board (COB) type, in which the LED 100 illustrated in FIGS. 1 and 2 may be bonded directly onto a substrate 910.

The substrate 910 may include a first metallic pattern 920 and a second metallic pattern 930. The first metallic pattern 920 and the second metallic pattern 930 may be formed in a form corresponding to positions, areas, and shapes of a first bump 170 and a second bump 160 included in the LED 100.

The LED 100 may be flip-chip bonded on the substrate 910 so that the first bump 170 and the second bump 160 may be bonded to the first metallic pattern 920 and the second metallic pattern 930. In this instance, the first bump 170 and the second bump 160 may occupy more than 90% of an area on a second semiconductor layer 123, and a percentage of a bonded area occupied by the substrate 910 and the LED 100 may be greater than 90% as well. Accordingly, the first bump 170 and the second bump 160 may perform an underfill function, and a separate underfill process may be omitted after the substrate 910 and the LED 100 are bonded.

The first bump 170 and the second bump 160 may have identical areas on the second semiconductor layer 123, whereby a bond performance between the first bump 170 and the first metallic pattern 920 and a bond performance between the second bump 160 and the second metallic pattern 930 may be balanced.

The first bump 170 and the second bump 160 may have identical heights based on the second semiconductor layer 123, whereby a chip separation phenomenon resulting from a difference in heights between the first bump 170 and the second bump 160 may be prevented.

According to embodiments of the present general inventive concept, an LED and a manufacturing method thereof may form a first bump and a second bump that have bilateral symmetry, and have identical areas and identical heights based on a light emitting structure, thereby improving a bond performance between the LED and a substrate and a heat emission efficiency in a process of manufacturing an LED module.

According to embodiments of the present general inventive concept, an LED and a manufacturing method thereof may increase an area occupied by a first bump and a second bump on a surface of a light emitting structure, thereby omitting an underfill process in a process of manufacturing an LED module.

According to embodiments of the present general inventive concept, an LED and a manufacturing method thereof may increase the diversity and number of different types of equipment that may be used to perform a bump manufacturing process and a flip chip bonding process, since designs of a first bump and a second bump may be changed easily, thereby reducing a manufacturing cost during mass production.

Although a few exemplary embodiments of the present general inventive concept have been shown and described, the present general inventive concept is not limited to the exemplary embodiments described. Instead, it would be appreciated by those skilled in the art that changes may be made to these exemplary embodiments without departing from the principles and spirit of the present general inventive concept , the scope of which is defined by the claims and their equivalents.

What is claimed is:

1. A light emitting device (LED), comprising:
a first semiconductor layer, an active layer, and a second semiconductor layer formed sequentially on a light-transmitting substrate;
a first electrode formed in an indented region of the first semiconductor layer by removing a part of the first semiconductor layer;
a second electrode formed on the second semiconductor layer;
a passivation layer formed on the first electrode and the second electrode to expose a region of the first electrode and a region of the second electrode;
a first bump formed in a first region including the first electrode exposed through the passivation layer, and extended to another region of the second electrode on which the passivation layer is formed; and
a second bump formed in a second region including the second electrode exposed through the passivation layer.

2. The LED of claim 1, wherein the second electrode comprises:
a plurality of electrode pads formed on the second semiconductor layer; and
an intermediate connecting pad formed on the plurality of electrode pads.

3. The LED of claim 1, wherein the first region and the second region have bilateral symmetry on the second semiconductor layer.

4. The LED of claim 1, wherein the first bump and the second bump have identical heights based on the second semiconductor layer.

5. The LED of claim 1, wherein the first region and the second region have identical areas.

6. A method of manufacturing a light emitting device (LED), the method comprising:
forming a first semiconductor layer, an active layer, and a semiconductor layer, sequentially, on a light-transmitting substrate;
removing a part of the first semiconductor layer to form an indent within the first semiconductor layer;
forming a first electrode within the indent of the first semiconductor layer;
forming a second electrode on the second semiconductor layer;
forming a passivation layer on the first electrode and the second electrode;
etching the passivation layer to expose a region of the first electrode and a region of the second electrode;
forming a first bump in a first region including the first electrode exposed through the passivation layer, and extended to another region of the second electrode on which the passivation layer is formed; and
forming a second bump in a second region including the second electrode exposed through the passivation layer.

7. The method of claim 6, wherein the forming of the second electrode comprises:
forming a plurality of electrode pads on the second semiconductor layer; and
forming an intermediate connecting pad on the plurality of electrode pads.

8. The method of claim 6, wherein the forming the first bump and the forming the second bump comprise:
disposing, on the second semiconductor layer, a mask including a hole at a position corresponding to the first region and the second region; and
screen-printing a metallic material on the hole.

9. The method of claim 6, wherein the forming of the first bump and the forming of the second bump comprise bumping a solder ball in the first region and the second region.

10. The method of claim 6, wherein the first region and the second region have bilateral symmetry on the second semiconductor layer.

11. The method of claim 6, wherein the forming of the first bump comprises forming the first bump to have a height identical to a height of the second bump based on the second semiconductor layer.

12. The method of claim 6, wherein the first region and the second region have identical areas.

13. The method of claim 6, wherein the passivation layer is formed of any one selected from a group consisting of silicon oxide (SiOₓ), silicon nitride (SiNₓ), and silicon oxy-nitride (SiOₓN_{y}).

14. A light emitting device (LED) module, comprising:
a substrate comprising a first metallic pattern and a second metallic pattern; and
at least one LED that is flip-chip bonded on the substrate, the at least one LED comprising:
a first electrode and a second electrode formed on a face of a light emitting structure,
a passivation layer formed on the first electrode and the second electrode to expose a region of the first electrode and a region of the second electrode,
a first bump formed in a first region including the first electrode exposed through the passivation layer, and extended to another region of the second electrode on which the passivation layer is formed, and bonded to the first metallic pattern, and
a second bump formed in a second region including the second electrode exposed through the passivation layer, and bonded to the second metallic pattern.

15. The LED module of claim 14, wherein the first bump and the second bump have identical heights based on the light emitting structure.
